(19) United States
(12) Patent Application Publication
(10) Pub. No.: US 2026/0123155 A1
(43) Pub. Date: Apr. 30, 2026

(54) DISPLAY APPARATUS

(71) Applicant: AUO Corporation, Hsinchu City (TW)

(72) Inventors: Yi-Sheng Jhao, Hsinchu City (TW); Yi-Yueh Hsu, Hsinchu City (TW); Kuan-Hsun Chen, Hsinchu City (TW)

(73) Assignee: AUO Corporation, Hsinchu City (TW)

(21) Appl. No.: 18/981,674

(22) Filed: Dec. 16, 2024

(30) Foreign Application Priority Data
Oct. 28, 2024 (TW) 113141016

(51) Int. Cl. H10H 29/852; H10H 29/855; H10H 29/856

(52) U.S. Cl. CPC H10H 29/852; H10H 29/8552; H10H 29/856

(57) ABSTRACT

A display apparatus includes a driving circuit substrate, a light emitting element, a first encapsulation layer and a second encapsulation layer. The light-emitting element is disposed on the driving circuit substrate and is electrically connected to the driving circuit substrate. The first encapsulation layer is disposed on the driving circuit substrate and has reflective particles. The first encapsulation layer includes a first portion and a second portion. The first portion is disposed on the driving circuit substrate and extends outward from the light-emitting element. The second portion is disposed on the first portion and covers a side wall of the light emitting element. A density of the reflective particles in the second portion is greater than a density of the reflective particles in the first portion. The second encapsulation layer is disposed on the first encapsulation layer and can absorb light.

### CROSS-REFERENCE TO RELATED APPLICATION

This application claims the priority benefit of Taiwan application serial no. 113141016, filed on Oct. 28, 2024. The entirety of the above-mentioned patent application is hereby incorporated by reference herein and made a part of this specification.

### BACKGROUND

### Technical Field

The disclosure relates to an optoelectronic device, and in particular to a display apparatus.

### Description of Related Art

A light-emitting diode display panel includes a driving circuit substrate and a plurality of light-emitting diode devices transferred onto the driving circuit substrate. Inheriting the characteristics of light-emitting diodes, the light-emitting diode display panel has advantages of power saving, high efficiency, high brightness, and fast response time. In addition, compared with an organic light-emitting diode display panel, the light-emitting diode display panel further has advantages of easy color adjustment, long light emission life, no image burn-in, etc. Therefore, the light-emitting diode display panel is considered as a display technology of the next generation.

Generally speaking, in order to increase the light extraction efficiency of the light-emitting diode element, a reflective adhesive layer can be formed on the driving circuit substrate so that the light beam emitted toward the side by the light-emitting diode element can be reflected and then light can be emitted. In order for the reflective adhesive layer to fully reflect the light beam emitted by the light-emitting diode element, the reflective adhesive layer needs to have considerable thickness. However, on the other hand, the reflective adhesive layer should not be so thick that it exceeds the top surface of the light-emitting diode element and affects the light emission. In other words, the thickness uniformity of the reflective adhesive layer is required to be very high, which makes the etching process margin used to form the reflective adhesive layer low, which is not conducive to mass production manufacturing.

### SUMMARY

One embodiment of this disclosure provides a display apparatus with a large process margin for the first encapsulation layer.

A display apparatus of an embodiment of this disclosure a driving circuit substrate, a light emitting element, a first encapsulation layer and a second encapsulation layer. The light emitting element is disposed on the driving circuit substrate and is electrically connected to the driving circuit substrate. The first encapsulation layer is disposed on the driving circuit substrate and has reflective particles. The first encapsulation layer includes a first portion and a second portion. The first portion is disposed on the driving circuit substrate and extends outward from the light emitting element. The second portion is disposed on the first portion and covers a side wall of the light emitting element. A density of the reflective particles in the second portion is greater than a density of the reflective particles in the first portion. The second encapsulation layer is disposed on the first encapsulation layer and can absorb light.

### BRIEF DESCRIPTION OF THE DRAWINGS

FIG. 1 is a schematic cross-sectional view of a display apparatus according to an embodiment of the present disclosure.

FIG. 2 is a photo of the light emitting element and the first encapsulation layer of the display apparatus of one embodiment of the disclosure taken using an electron microscope.

FIG. 3 shows the undulations on the surface of the first encapsulation layer according to an embodiment of the present disclosure.

FIG. 4 shows the undulations on the surface of the second encapsulation layer according to one embodiment of the present disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

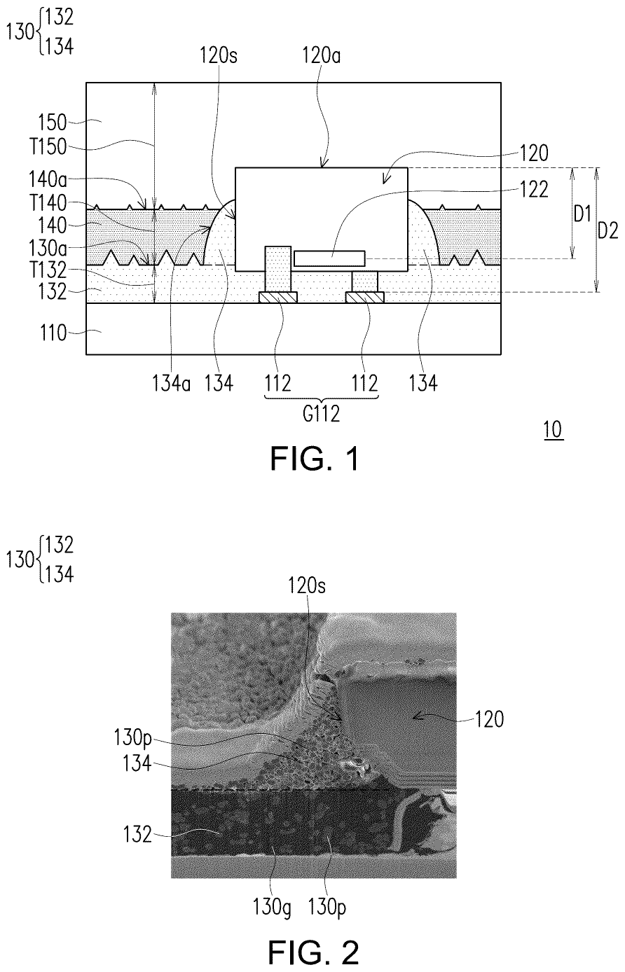

FIG. 1 is a schematic cross-sectional view of a display apparatus according to an embodiment of the present disclosure. FIG. 2 is a photo of the light emitting element and the first encapsulation layer of the display apparatus of one embodiment of the disclosure taken using an electron microscope.

Referring to FIG. 1, a display apparatus 10 includes a driving circuit substrate 110 having a sub-pixel driver structure. In some embodiments, the sub-pixel driver structure may include a sub-pixel drive circuit (not shown) and a bonding pad group G112 electrically connected to the sub-pixel drive circuit, wherein the bonding pad group G112 includes at least one bonding pad 112.

For example, in some embodiments, the sub-pixel drive circuit may include a first transistor (not shown), a second transistor (not shown) and a capacitor (not shown), wherein a first terminal of the first transistor is electrically connected to a corresponding data line (not shown), a control terminal of the first transistor is electrically connected to a corresponding scan line (not shown), and a second terminal of the first transistor is electrically connected to a corresponding scan line (not shown). The second terminal of the first transistor is electrically connected to a control terminal of the second transistor, a first terminal of the second transistor is electrically connected to a corresponding power line (not shown), and the capacitor is electrically connected to the second terminal of the first transistor and the first terminal of the second transistor. The second terminal of the second transistor is electrically connected to a bonding pad 112 of a corresponding bonding pad group G112, and another bonding pad 112 of the bonding pad group G112 is electrically connected to a common line (not shown). However, this disclosure is not limited to this. In other embodiments, the sub-pixel drive circuit may be other forms of circuits.

Referring to FIG. 1, the display apparatus 10 further includes a light emitting element 120 disposed on the driving circuit substrate 110 and electrically connected to the driving circuit substrate 110. Specifically, in some embodiments, the light emitting element 120 is bonded to the bonding pad group G112 of the driving circuit substrate 110 and is electrically connected to the sub-pixel drive circuit (not shown) of the driving circuit substrate 110 through the bonding pad group G112. The light emitting element 120 has a light emitting layer 122. For example, in some embodiments, the light emitting element 120 may be a micro light emitting diode (μLED), and the light emitting layer 122 may be an active layer located between the first type semiconductor layer (not labeled) and the second type semiconductor layer (not labeled) of the light emitting element 120.

Referring to FIGS. 1 and 2, the display apparatus 10 further includes a first encapsulation layer 130 disposed on the driving circuit substrate 110 and has reflective particles 130p. The first encapsulation layer 130 further has a first encapsulation material 130g, and the reflective particles 130p are distributed in the first encapsulation material 130g. In some embodiments, the reflective particles 130p are, for example, titanium dioxide (TiO2) particles, and the first encapsulation layer 130 is, for example, made of cured white glue, but this disclosure is not limited to thereto.

The first encapsulation layer 130 includes a first portion 132 and a second portion 134. The first portion 132 is disposed on the driving circuit substrate 110 and extends outward from the light emitting element 120. The second portion 134 is disposed on the first portion 132 and covers a side walls 120s of the light emitting element 120. In some embodiments, the first portion 132 of the first encapsulation layer 130 is generally located below the light emitting layer 122 of the light emitting element 120, and the second portion 134 of the first encapsulation layer 130 is generally located next to and above the light emitting layer 122, but this disclosure is not limited thereto. In some embodiments, the first portion 132 of the first encapsulation layer 130 substantially occupies an area of the driving circuit substrate 110 directly below the light emitting element 120 and an area of the driving circuit substrate 110 not occupied by the light emitting element 120, the first portion 132 of the first encapsulation layer 130 covers the bonding pads 112, and the second portion 134 of the first encapsulation layer 130 surrounds the light emitting element 120 and covers the side walls 120s of the light emitting element. In some embodiments, the second portion 134 may have an inclined surface 134a that is inclined relative to the driving circuit substrate 110.

In some embodiments, the second portion 134 of the first encapsulation layer 130 may be higher than the light emitting layer 122 of the light emitting element 120. In some embodiments, the light emitting element 120 has a top surface 120a facing away from the driving circuit substrate 110, and the first encapsulation layer 130 does not cover the top surface 120a of the light emitting element 120. That is to say, in some embodiments, the first encapsulation layer 130 does not cover a main light emitting surface of the light emitting element 120.

It is worth noting that a density of the reflective particles 130p in the second portion 134 of the first encapsulation layer 130 is greater than a density of the reflective particles 130p in the first portion 132. For example, in some embodiments, the density of the reflective particles 130p in the second portion 134 of the first encapsulation layer 130 is greater than 40%, and the density of the reflective particles 130p in the first portion 132 of the first encapsulation layer 130 is less than 40%, but this disclosure is not limited to thereto. In some embodiments, the density of the reflective particles 130p in the first portion 132 of the first encapsulation layer 130 may refer to: in a cross section of the first encapsulation layer 130, a ratio of the sum of areas of the reflective particles 130p located in the first portion 132 to an area of the first portion 132 (including the first encapsulation material 130g and the reflective particles 130p) of the first encapsulation layer 130; the density of the reflective particles 130p in the second portion 134 of the first encapsulation layer 130 may refer to: in a cross section of the first encapsulation layer 130, an ratio of the sum of areas of the reflective particles 130p located in the second portion 134 to an area of the second portion 134 of the first encapsulation layer 130.

In some embodiments, the first encapsulation layer 130 with a special second portion 134 may be formed by adjusting etching process parameters. Adjusting the etching process parameters can make the second portion 134 of the first encapsulation layer 130 cover the light emitting element 120. This method can increase the etching process margin for making the first encapsulation layer 130.

Referring to FIG. 1, in some embodiments, a distance D1 from the top surface 120a of the light emitting element 120 to the light emitting layer 122 of the light emitting element 120 is, for example, 5 μm, a distance D2 from the top surface 120a of the light emitting element 120 to the bonding pad 112 is, for example, 7 μm, and a thickness T132 of the first portion 132 of the first encapsulation layer 130 falls, for example, in a range of 1 μm˜3 μm, but this disclosure is not limited to thereto.

Referring to FIG. 1, the display apparatus 10 further includes a second encapsulation layer 140 which is disposed on the first encapsulation layer 130 and can absorb light. The top surface 120a of the light emitting element 120 is higher than the second encapsulation layer 140. In some embodiments, the second encapsulation layer 140 includes a second encapsulation material (not shown) and light-absorbing particles (not shown) distributed in the second encapsulation material. In some embodiments, the light-absorbing particles are, for example, carbon black particles, and the second encapsulation layer 140 is, for example, made of cured black glue, but this disclosure is not limited to thereto. In some embodiments, a thickness T140 of the second encapsulation layer 140 is greater than 2 μm. In some embodiments, a thickness T140 of the second encapsulation layer 140 falls in a range of 2 μm to 4 μm, for example, but this disclosure is not limited to thereto.

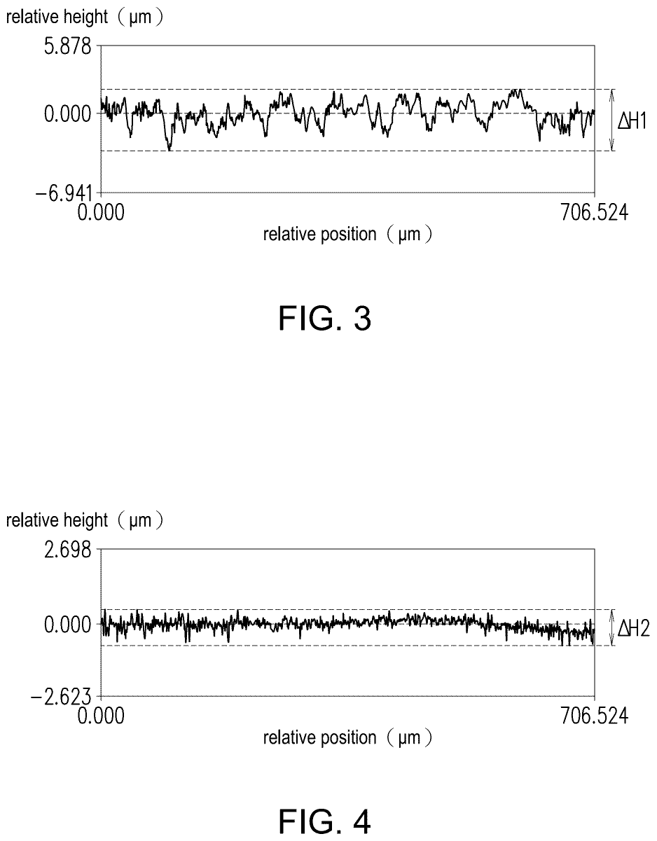

FIG. 3 shows the undulations on the surface of the first encapsulation layer according to an embodiment of the present disclosure. FIG. 4 shows the undulations on the surface of the second encapsulation layer according to one embodiment of the present disclosure. Referring to FIGS. 1, 3 and 4, in some embodiments, the surface roughness of the surface 130a of the first encapsulation layer 130 is greater than the surface roughness of the surface 140a of the second encapsulation layer 140. For example, in some embodiments, the surface 130a of the first encapsulation layer 130 may be an uneven rough surface, and the height difference ΔH1 of the uneven rough surface of the first encapsulation layer 130 may fall within the range of ±5 μm (properly, fall within the range of ±2 μm); the surface 140a of the second encapsulation layer 140 can be an uneven rough surface, the height difference ΔH2 of the uneven rough surface of the second encapsulation layer 140 may fall within the range of ±2 μm (properly, fall within the range of ±0.5 μm), but this disclosure is not limited to thereto.

Referring to FIG. 1, in some embodiments, the display apparatus 10 further includes a translucent encapsulation layer 150 covering the second encapsulation layer 140 and the light emitting element 120. In some embodiments, the translucent encapsulation layer 150 may be a translucent glue layer. The light emitting element 120 is located between the translucent encapsulation layer 150 and the first encapsulation layer 130. The second encapsulation layer 140 is located between the translucent encapsulation layer 150 and the first encapsulation layer 130. In some embodiments, the second portion 134 of the first encapsulation layer 130 may protrude from the second encapsulation layer 140, and the translucent encapsulation layer 150 may contact the second portion 134 of the first encapsulation layer 130, but this disclosure is not limited thereto. In some embodiments, the thickness T150 of the translucent encapsulation layer 150 is, for example, about 30 μm, but this disclosure is not limited to thereto.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display apparatus comprising:
a driving circuit substrate;
a light emitting element, disposed on the driving circuit substrate and electrically connected to the driving circuit substrate;
a first encapsulation layer, disposed on the driving circuit substrate and has reflective particles, wherein the first encapsulation layer comprises:
a first portion, disposed on the driving circuit substrate and extending outward from the light emitting element; and
a second portion, disposed on the first portion and covering a side wall of the light emitting element, wherein a density of the reflective particles in the second portion is greater than a density of the reflective particles in the first portion; and
a second encapsulation layer, disposed on the first encapsulation layer and can absorb light.

2. The display apparatus according to claim 1, wherein the density of the reflective particles in the second portion is greater than 40%, and the density of the reflective particles in the first portion is less than 40%.

3. The display apparatus according to claim 1, wherein a surface roughness of the first encapsulation layer is greater than a surface roughness of the second encapsulation layer.

4. The display apparatus according to claim 1, wherein the second portion of the first encapsulation layer protrudes from the second encapsulation layer.

5. The display apparatus according to claim 4, further comprising:
a translucent encapsulation layer covering the second encapsulation layer and the light emitting element and contacting the second portion of the first encapsulation layer.

6. The display apparatus according to claim 1, wherein the reflective particles comprise titanium dioxide particles.

7. The display apparatus according to claim 1, wherein the second portion of the first encapsulation layer is located next to and above a light emitting layer of the light emitting element.

8. The display apparatus according to claim 1, wherein the second portion has an inclined surface that is inclined relative to the driving circuit substrate.

9. The display apparatus according to claim 1, wherein the second portion of the first encapsulation layer is higher than a light emitting layer of the light emitting element.

10. The display apparatus according to claim 1, wherein the first encapsulation layer does not cover a top surface of the light emitting element.

11. The display apparatus according to claim 1, wherein the second encapsulation layer comprises an encapsulation material and light-absorbing particles distributed in the encapsulation material.

12. The display apparatus according to claim 1, wherein a thickness of the second encapsulation layer is greater than 2 μm.

13. The display apparatus according to claim 1, wherein a height difference of an uneven rough surface of the first encapsulation layer falls within a range of ±5 μm.

14. The display apparatus according to claim 1, wherein a height difference of an uneven rough surface of the second encapsulation layer falls within a range of ±2 μm.

15. The display apparatus according to claim 1, further comprising:
a translucent encapsulation layer covering the second encapsulation layer and the light emitting element.

16. The display apparatus according to claim 15, wherein the second portion of the first encapsulation layer protrudes from the second encapsulation layer, and the translucent encapsulation layer contacts the second portion of the first encapsulation layer.
